(19) United States
(12) Patent Application Publication
(10) Pub. No.: US 2024/0389320 A1
(43) Pub. Date: Nov. 21, 2024

(54) NON-VOLATILE MEMORY CELL

(71) Applicant: FUH-CHENG JONG, TAINAN CITY (TW)

(72) Inventor: FUH-CHENG JONG, TAINAN CITY (TW)

(21) Appl. No.: 18/581,749

(22) Filed: Feb. 20, 2024

(30) Foreign Application Priority Data
May 17, 2023 (TW) 112118349

(51) Int. Cl. H10B 41/30; H01L 29/10; H01L 29/78; H01L 29/788

(52) U.S. Cl. CPC H10B 41/30; H01L 29/1083; H01L 29/785; H01L 29/7881

(57) ABSTRACT

A non-volatile memory cell includes at least one unit cell. Each unit cell includes a fin channel, a source, a drain, a first part, a second part, and a third part. The first part includes a first floating gate and a first control valve. The second part includes a second floating gate and a second control valve. The third part includes a third floating gate and a third control gate. The unit cell can store three bits of data.

### FIELD OF THE INVENTION

The present invention relates to a non-volatile memory cell, and more particularly to a fin-shaped non-volatile memory cell having at least one unit cell. Each unit cell can store two or three bits of data.

### BACKGROUND OF THE INVENTION

Non-volatile memory (NVM) is a type of memory component that is widely used in computers and various electronic devices, as it can keep stored data without an external power source. In order to meet market demand, existing non-volatile memory technology is developing toward high density and fast read, program and erase.

Taiwan Patent Publication No. 1642182 discloses a fin-based non-volatile memory structure, comprising a substrate and a dual-bit non-volatile memory structure on top of the substrate. The two-bit structure includes a main fin structure, first and second fin structures adjacent to the main fin structure. The fin structures are parallel and extend transversely on the substrate. The main fin structure include a source, a channel, and a drain. The first and second fin structures each include a program/erase gate. The dual-bit structure further includes a first floating gate between the channel of the main fin structure and the first fin structure and a second floating gate positioned between the channel of the main fin structure and the second fin structure. The dual-bit structure further includes a control gate adjacent to the main fin structure.

Taiwan Patent Publication No. 1700819 discloses a non-volatile memory. The memory cell includes a source region, a drain region, a selection gate, a virtual selection gate, a floating gate, an erase gate, and a control gate. The selection gate is disposed on the substrate between the source region and the drain region. The floating gate is disposed on the substrate between the selection gate and the source region. Two symmetrical corner parts are disposed on both sides of the top of the floating gate. The floating gate is higher than the selection gate and the virtual select gate. The erase gate is arranged on the source region. The erase gate covers the corner part on the sides of the floating gate. The control gate is arranged on the erase gate and the floating gate.

However, in aforementioned U.S. Pat. No. 1,642,182, a program/erase gate junction region is required and the area of the components is large, which is not conducive to increasing the density of non-volatile memory. The aforementioned U.S. Pat. No. 1,700,819 increases the difficulty of the manufacturing process due to the number of gates.

### SUMMARY OF THE INVENTION

According to one aspect of the present invention, a non-volatile memory cell is provided. The non-volatile memory cell comprises at least one unit cell. The unit cell includes a fin channel, extending in a Y direction; a source, adjacent to one end of the fin channel in the Y direction; a drain, adjacent to another end of the fin channel in the Y direction; an oxide layer, including a first oxide layer, a second oxide layer and a third oxide layer; a floating gate, including a first floating gate, a second floating gate and a third floating gate; an insulating layer, including a first insulating layer, a second insulating layer and a third insulating layer; a control gate, including a first control gate, a second control gate and a third control gate; a first part, adjacent to one side of the fin channel in an X direction, the X direction being perpendicular to the Y direction, the first part including, in sequence, the first oxide layer close to the fin channel, the first floating gate, the first insulating layer, and the first control gate far away from the fin channel; a second part, adjacent to another side of the fin channel in the X direction, the second part including, in sequence, the second oxide layer close to the fin channel, the second floating gate, the second insulating layer, and the second control gate far away from the fin channel; and a third part, adjacent to the fin channel in a Z direction, the Z direction being perpendicular to the X direction and the Y direction, the third part including the third oxide layer close to the fin channel, the third floating gate, the third insulating layer, and the third control gate far away from the fin channel.

According to another aspect of the present invention, a non-volatile memory cell is provided. The non-volatile memory cell comprises at least one unit cell. The unit cell includes a fin channel, extending in a Y direction; a source, adjacent to one end of the fin channel in the Y direction; a drain, adjacent to another end of the fin channel in the Y direction; a first part, adjacent to one side of the fin channel in an X direction, the X direction being perpendicular to the Y direction; a second part, adjacent to another side of the fin channel in the X direction; and a third part, adjacent to the fin channel in a Z direction, the Z direction being perpendicular to the X direction and the Y direction. Two of the first part, the second part and the third part each include, in sequence, an oxide layer close to the fin channel, a floating gate, an insulating layer, and a control gate far away from the fin channel. The remaining one of the first part, the second part and the third part includes, in sequence, the insulating layer close to the fin channel and the control gate far away from the fin channel. The control gate of the first part is defined as a first control gate. The control gate of the second part is defined as a second control gate. The control gate of the third part is defined as a third control gate.

Preferably, the oxide layer includes one of silicon dioxide, hafnium dioxide and zirconium dioxide, or a combination thereof. The insulating layer includes one of silicon dioxide, zirconium dioxide, hafnium dioxide and silicon nitride, or a combination thereof.

Preferably, the fin channel includes a first substrate adjacent to the drain, an anti-punch-through region adjacent to the first substrate, and a second substrate adjacent to the anti-punch-through region and the source.

Preferably, the first control gate is connected to a first bias voltage. The second control gate is connected to a second bias voltage. The third control gate is connected to a third bias voltage. The drain is connected to a fourth bias voltage. The source is connected to a fifth bias voltage. The unit cell is operated in one of a stand-by state, a read state, a program state and an erase state. When in the stand-by state, the first bias voltage, the second bias voltage and the third bias voltage are negative bias voltages, the fourth bias voltage is a zero bias voltage or positive bias voltage, and the fifth bias voltage is a zero bias voltage. When in the read state, one of the first bias voltage, the second bias voltage and the third bias voltage and the fourth bias voltage are positive bias voltages, the fifth bias voltage is a zero bias voltage, the remaining two of the first bias voltage, the second bias voltage and the third bias voltage are negative bias voltages. When in the program state, one of the first bias voltage, the second bias voltage and the third bias voltage and the fourth bias voltage are positive bias voltages, the fifth bias voltage is a zero bias voltage, and the remaining two of the first bias voltage, the second bias voltage and the third bias voltage are negative bias voltages and are maintained for a first time. When in the erase state, one of the first bias voltage, the second bias voltage and the third bias voltage is a negative bias voltage, the remaining two of the first bias voltage, the second bias voltage and the third bias voltage are zero bias voltages or positive bias voltages. Both the fourth bias voltage and the fifth bias voltage are positive bias voltages and are maintained for a second time.

Preferably, when the unit cell is operated in the stand-by state, the first bias voltage, the second bias voltage and the third bias voltage are between −3 and +0 volts, respectively. When the unit cell is operated in one of the read state, the program state and the erase state, the first bias voltage, the second bias voltage, the third bias voltage, the fourth bias voltage and the fifth bias voltage are between −10 and +20 volts, respectively.

Preferably, a control unit is electrically connected to the unit cell. After the unit cell is operated in the program state or the erase state, the unit cell is operated in the read state and the control unit executes a check process. When the control unit detects an error through the check process, the unit cell is operated in the program state or the erase state again, and then is operated in the read state, the control unit re-executes the check process, and the control unit counts the number of checks. The control unit erases the number of checks until the control unit detects that there is no error through the check process; or the control unit outputs an abnormal message when the number of checks is greater than an allowable number.

Preferably, both the first time of the program state and the second time of the erase state are less than one second.

Preferably, the control gate is doped with an impurity. The impurity includes one of phosphorus, arsenic, antimony, boron and aluminum, or a combination thereof.

Preferably, the source, the drain and the fin channel are each doped with an impurity having a same polarity. When the unit cell is an n-type channel cell, the impurity doped in the source and the drain includes one of phosphorus, arsenic and antimony, or a combination thereof. When the unit cell is a p-type channel cell, the impurity doped in the source and the drain includes boron and/or aluminum.

Preferably, the impurity doped on a surface of the fin channel has a surface concentration. A concentration of the impurity doped below the fin channel is lower than the surface concentration at a depth near the surface of the fin channel. Below the depth, the concentration of the impurity increases to a multiple of the surface concentration and then gradually decreases in the Z-direction.

Preferably, the at least one unit cell includes a plurality of unit cells. The drains of the unit cells are connected to each other and the sources of the unit cells are connected to each other to form a NOR structure.

Alternatively, the at least one unit cell includes a plurality of unit cells. The source of at least one of the unit cells is connected to the drain of an adjacent one of the unit cells to form a NAND logic gate structure.

According to the above technical features, the present invention can achieve the following effects:
1. The source and the drain are disposed at both ends of the fin channel in the Y direction. The first floating gate/the first control gate and the second floating gate/the second control gate are disposed at both sides of the fin channel in the X direction, respectively. The third floating gate and the third control gate are disposed on top of the fin channel in the Z direction. The unit cell can store three bits of data, which is beneficial to reduce the size while increasing the memory capacity, and even simplify the manufacturing process and reduce production costs.
2. When in the stand-by state, the third bias voltage is a negative bias voltage, which can reduce the punch-through current between the source and the drain, avoid unnecessary power waste, and prevent a data error caused by an unintended leakage current of the first floating gate or the second floating gate.
3. The source, the drain and the fin channel are each doped with the impurity having the same polarity, which can reduce the punch-through rate due to short-channel effects and improve the product yield.
4. In addition to providing the insulating function, the insulating material between the floating gate and the control gate can increase the dielectric coefficient value of the dielectric of the parasitic capacitance formed by the floating gate and the control gate, thereby increasing the couple ratio and reducing the voltage of the control gate.

### BRIEF DESCRIPTION OF THE DRAWINGS

FIG. 1 is a perspective view according to a first embodiment the present invention;

FIG. 2 is a perspective view of the source, the fin channel and the drain according to the first embodiment the present invention;

FIG. 3 is a front view according to the first embodiment the present invention, viewed in the Y direction;

FIG. 4 is a first cross-sectional view taken along line IV-IV of FIG. 1 according to the first embodiment the present invention;

FIG. 5 is a side view according to the first embodiment the present invention, viewed in a direction opposite to the X direction;

FIG. 6 is a second cross-sectional view taken along line VI-VI of FIG. 1 according to the first embodiment the present invention;

FIG. 7 is a top view according to the first embodiment the present invention, viewed in a direction opposite to the Z direction;

FIG. 8 is a first schematic view of the implementation according to the first embodiment the present invention, illustrating that a plurality of unit cells are disposed on the chip and combined to form a first non-volatile memory;

FIG. 9 is a second schematic view of the implementation according to the first embodiment the present invention, illustrating that a plurality of unit cells are combined to form a first example of the non-volatile memory;

FIG. 10 is a third schematic view of the implementation according to the first embodiment the present invention, illustrating that a plurality of unit cells are combined to form a second example of the non-volatile memory; and

FIG. 11 is a perspective view according to a second embodiment the present invention.

### DETAILED DESCRIPTION OF THE PREFERRED EMBODIMENTS

Embodiments of the present invention will now be described, by way of example only, with reference to the accompanying drawings.

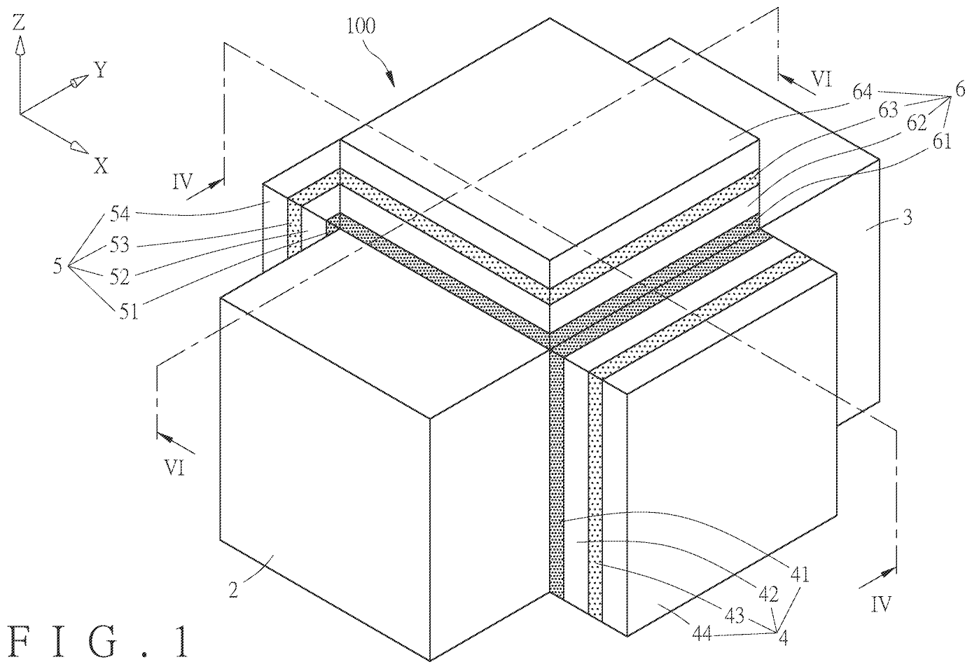

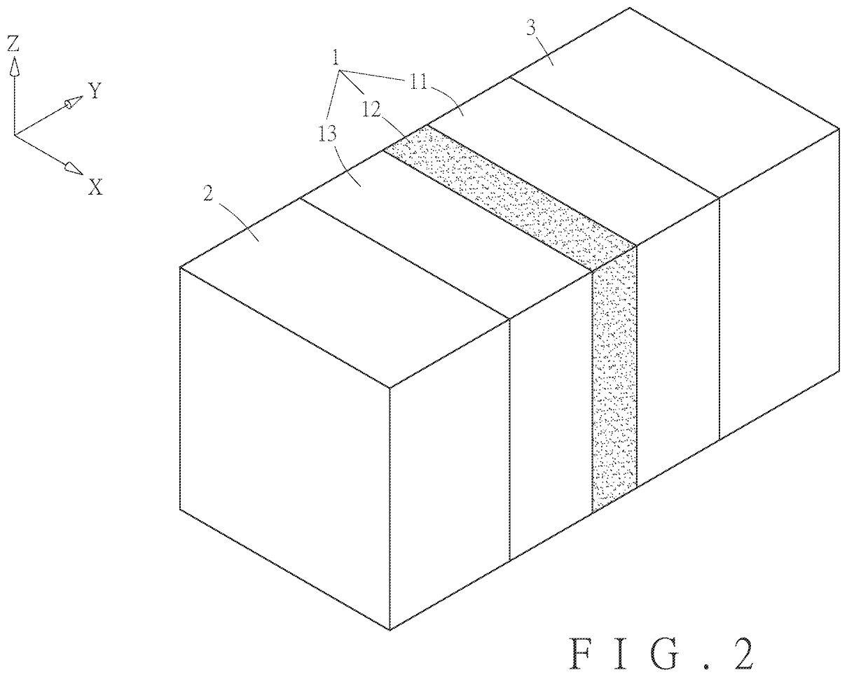

The present invention disclose a non-volatile memory cell. FIG. 1 and FIG. 2 illustrate a first embodiment of the non-volatile memory cell provided by the present invention, comprising a plurality of unit cells 100, which is a field-effect transistor having a fin-like appearance.

The unit cell 100 includes a fin channel 1, a source 2, a drain 3, a first part 4, a second part 5, and a third part 6.

The fin channel 1 extends in a Y direction. The Y direction is perpendicular to an X direction and a Z direction.

The fin channel 1 includes a first substrate 11, an anti-punch-through region 12 adjacent to the first substrate 11, and a second substrate 13 adjacent to the anti-punch-through region 12.

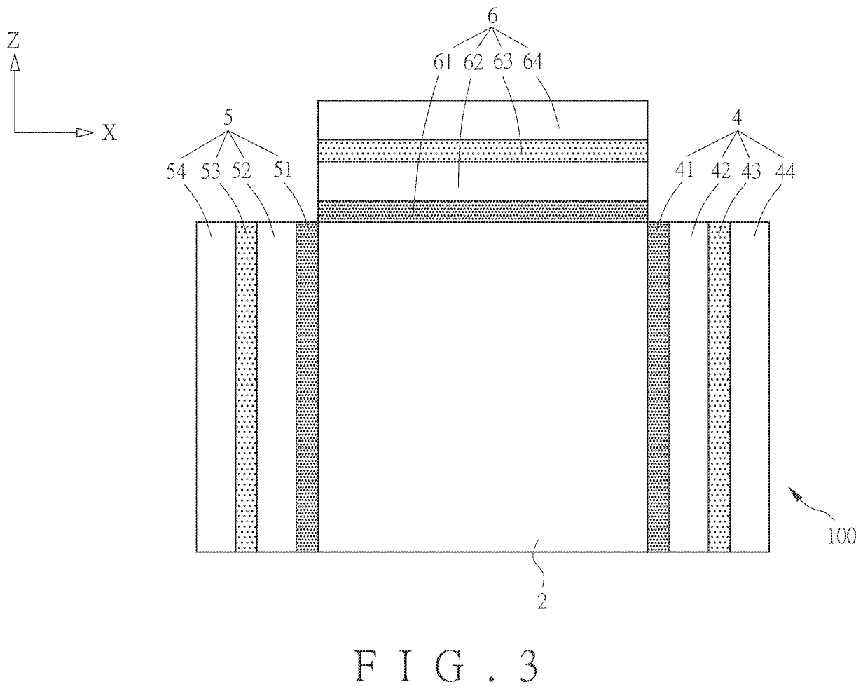

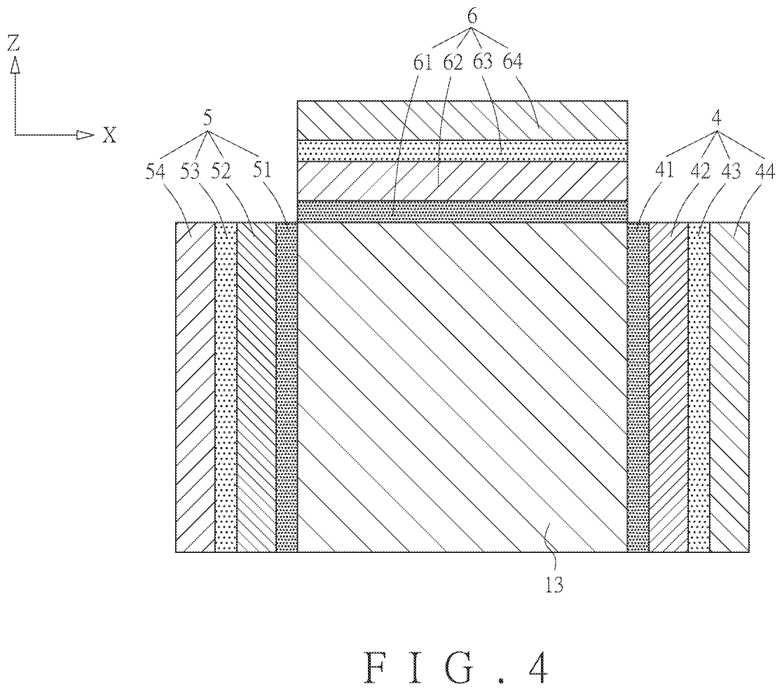

Referring to FIG. 3 and FIG. 4, the first part 4 is adjacent to one side of the fin channel 1 in the X direction, and the second part 5 is adjacent to the other side of the fin channel 1 in the X direction.

The first part 4 includes, in sequence, a first oxide layer 41 close to the fin channel 1, a first floating gate 42, a first insulating layer 43, and a first control gate 44 far away from the fin channel 1. The second part 5 includes, in sequence, a second oxide layer 51 close to the fin channel 1, a second floating gate 52, a second insulating layer 53, and a second control gate 54 far away from the fin channel 1.

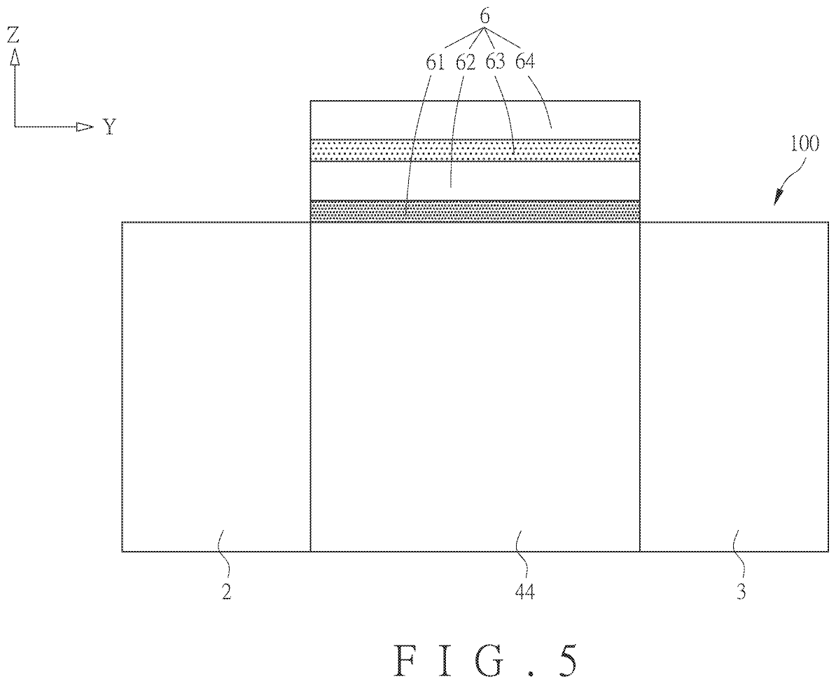

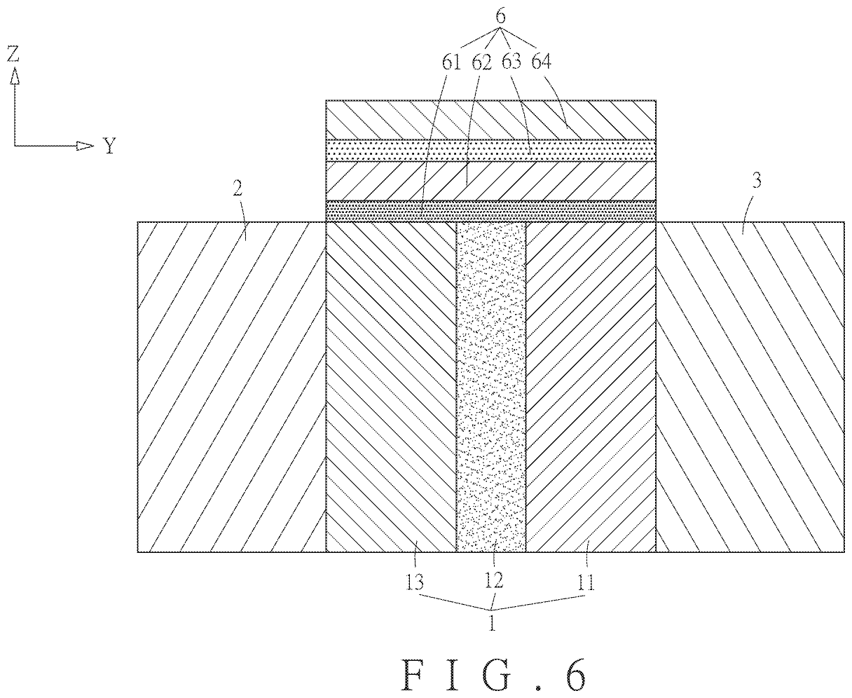

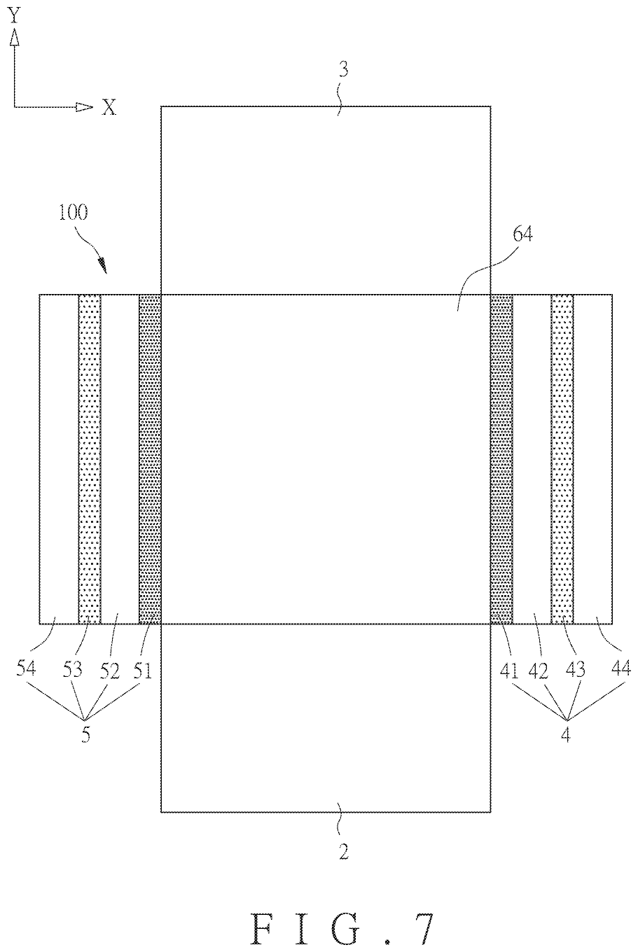

Referring to FIG. 5 through FIG. 7, the source 2 is located at one end of the fin channel 1 in the Y direction and adjacent to the second substrate 13. The drain 3 is located at the other end of the fin channel 1 in the Y direction and adjacent to the first substrate 11.

The third part 6 is adjacent to the fin channel 1 in the Z direction.

The third part 6 includes a third oxide layer 61 close to the fin channel 1, a third floating gate 62, a third insulating layer 63, and a third control gate 64 far away from the fin channel 1.

The first oxide layer 41, the second oxide layer 51 and the third oxide layer 61 are each an oxide layer. The first floating gate 42, the second floating gate 52 and the third floating gate 62 are each a floating gate. The first insulating layer 43, the second insulating layer 53 and the third insulating layer 63 are each an insulating layer. The first control gate 44, the second control gate 54 and the third control gate 64 are each a control gate.

In this embodiment, the first control gate 44, the second control gate 54 and the third control gate 64 are each doped with an impurity. The impurity includes one of phosphorus, arsenic, antimony, boron and aluminum, or a combination thereof.

The source 2, the drain 3 and the fin channel 1 are each doped with the impurity having the same polarity. The impurity doped on the surface of the fin channel 1 has a surface concentration. The concentration of the impurity doped below the fin channel 1 is lower than the surface concentration at a depth near the surface of the fin channel 1. Below the depth, the concentration of the impurity increases to a multiple of the surface concentration and then gradually decreases in the Z-direction. Since the impurities have the same polarity, the punch-through rate due to short-channel effects can be reduced and the product yield can be improved.

When the unit cell 100 is an n-type channel cell, the impurity doped in the source 2 and the drain 3 includes one of phosphorus, arsenic and antimony, or a combination thereof.

When the unit cell 100 is a p-type channel cell, the impurity doped in the source 2 and the drain 3 includes boron and/or aluminum.

In this embodiment, the polarity of the source 2 and the drain 3 after being doped with the impurity is n+ type. The first substrate 11 and the second substrate 13 are p-type.

The components of the first oxide layer 41, the second oxide layer 51 and the third oxide layer 61 include one of silicon dioxide, hafnium dioxide and zirconium dioxide, or a combination thereof. For example, the above-mentioned materials are mixed to form the first oxide layer 41, the second oxide layer 51 and the third oxide layer 61, alternatively, the above-mentioned materials are each made into a platy structure having a certain thickness and then stacked on one another at a specific thickness ratio to form the first oxide layer 41, the second oxide layer 51 and the third oxide layer 61, but not limited thereto.

The components of the first insulating layer 43, the second insulating layer 53 and the third insulating layer 63 include one of silicon dioxide, zirconium dioxide, hafnium dioxide and silicon nitride, or a combination thereof. Similar to the first oxide layer 41, the second oxide layer 51 and the third oxide layer 61, the first insulating layer 43, the second insulating layer 53 and the third insulating layer 63 may be formed by mixing different materials, alternatively, different materials are each made into a platy structure having a certain thickness and then stacked on one another at a specific thickness ratio.

In addition to proving the insulating function, the first insulating layer 43, the second insulating layer 53 and the third insulating layer 63 can increase the dielectric coefficient value of the dielectric of the parasitic capacitance formed by each floating gate and each control gate, thereby increasing the couple ratio and reducing the voltage of the control gate.

The first floating gate 42, the first control gate 44, the second floating gate 52, the second control gate 54, the third oxide layer 61 and the third control gate 64 may be produced using, for example, a polycrystalline silicon material.

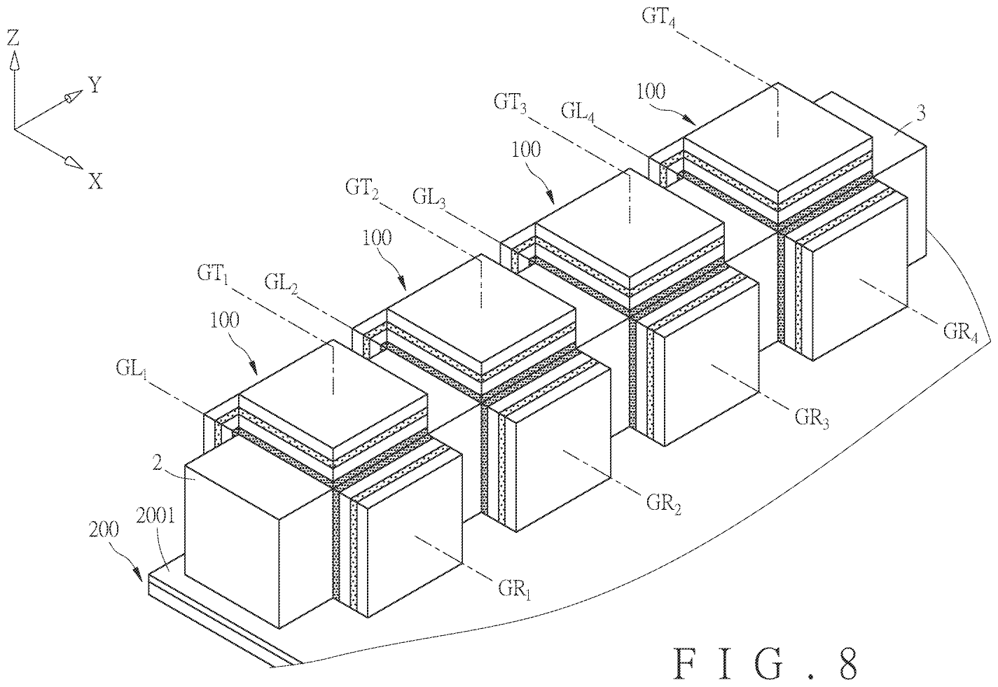

The first control gate 44 is connected to a first bias voltage GR₁, GR₂, GR₃, GR₄, GRₙ, the second control gate 54 is connected to a second bias voltage GL₁, GL₂, GL₃, GL₄, GLₙ, the third control gate 64 is connected to a third bias voltage GT₁, GT₂, GT₃, GT₄, GTₙ, the drain 3 is connected to a fourth bias voltage GD, and the source 2 is connected to a fifth bias voltage, as shown in FIG. 8 to FIG. 10.

The unit cell 100 is operated in one of a stand-by state, a read state, a program state, and an erase state.

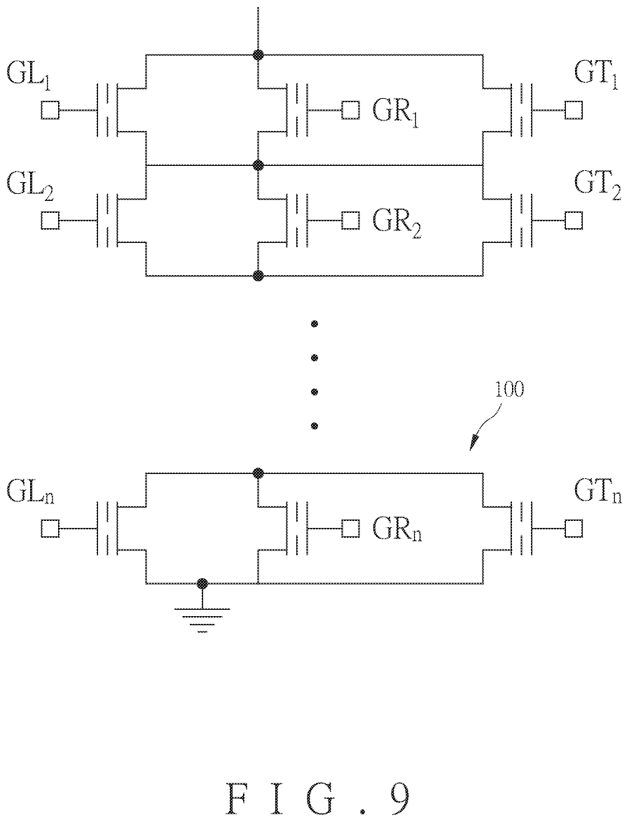

Referring to FIG. 1, FIG. 8 and FIG. 9, a first type of non-volatile memory may be produced by combining at least two unit cells 100 on top of a wafer 200.

In more detail, in the Z direction, an insulating layer 2001 is disposed on top of the wafer 200. The unit cells 100 are adjacently bonded on top of the insulating layer 2001 of the wafer 200.

In the unit cells 100, the source 2 of at least one of the unit cells 100 is connected to the drain 3 of an adjacent one of the unit cells 100 to form a NAND logic gate structure.

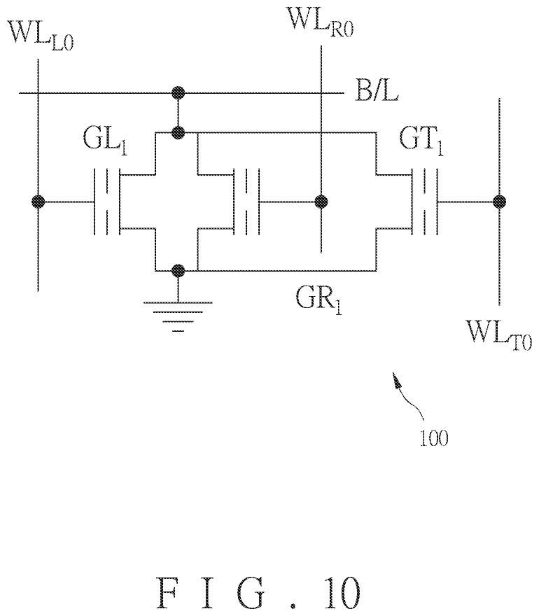

Referring to FIG. 1 and FIG. 10, a second type of non-volatile memory may be produced by arranging the unit cells 100 in a different manner from the first type of non-volatile memory.

In the unit cells 100, the drain 3 of at least one of the unit cells 100 is connected to the drain 3 of an adjacent one of the unit cells 100 and the source 2 of the at least one of the unit cells 100 is connected to the source 2 of the adjacent one of the unit cells 100 to form a NOR logic gate structure.

The NOR structure of the second type of non-volatile memory is illustrated. When in the stand-by state, the first bias voltage GR₁, the second bias voltage GL₁, and the third bias voltage GT₁ are all negative bias voltages, the fourth bias voltage is a zero bias voltage or positive bias voltage, and the fifth bias voltage is a zero bias voltage.

When in the read state, one of the first bias voltage GR₁, the second bias voltage GL₁ and the third bias voltage GT₁ and the fourth bias voltage are positive bias voltages, the remaining two of the first bias voltage GR₁, the second bias voltage GL₁ and the third bias voltage GT₁ are negative bias voltages, and the fifth bias voltage is a zero bias voltage.

When in the read state, according to the amount of current received by the first floating gate 42, the second floating gate 52 or the third floating gate 62 that is connected to the positive bias voltage, it can be determined that the data stored in the first floating gate 42, the second floating gate 52, or the third floating gate 62 is 0 or 1.

More specifically, for reading the unit cells 100 of the NOR structure, the digital signals stored in the unit cells 100 are read from the bit line B/L.

At this time, only the gate to be read, such as the first control gate 44, is connected to the high voltage (5 volts) through the word line WL_{L0}, and the gates of the other adjacent unit cells 100 (not shown), unselected gates, and the other two word lines WL_{R0} and WL_{T0} are not connected to the high voltage to avoid affecting reading.

For reading one of the unit cells 100 of the NAND structure, the rest of the word lines are first connected to a higher voltage, and the word line connected to this unit cell 100 is connected to a lower, normal voltage. Finally, the digital signal stored in the unit cell 100 is read from the bit line. The word lines and bit lines of the NAND structure are not shown in FIG. 9.

Next, the NOR structure of the second type of non-volatile memory is illustrated. When in the program state, one of the first bias voltage GR₁, the second bias voltage GL₁ and the third bias voltage GT₁ and the fourth bias voltage are positive bias voltages, the fifth bias voltage is a zero bias voltage, and the remaining two of the first bias voltage GR₁, the second bias voltage GL₁ and the third bias voltage GT₁ are negative bias voltages and are maintained for a first time.

During the first time, since the fin channel 1 is energized, the generated thermoelectrons enter the first floating gate 42, the second floating gate 52 or the third floating gate 62 that is connected to the positive bias voltage, so as to complete the program of data.

Since each unit cell 100 has the first floating gate 42, the second floating gate 52 and the third floating gate 62, three bits of data can be stored in the same unit cell 100, which is beneficial to increase memory capacity. The first insulating layer 43, the second insulating layer 53 and the third insulating layer 63 prevent the loss of stored charges in the first floating gate 42, the second floating gate 52 and the third floating gate 62 from causing a change in data.

When in the erase state, one of the first bias voltage GR₁, the second bias voltage GL₁ and the third bias voltage GT₁ is a negative bias voltage, the remaining two of the first bias voltage GR₁, the second bias voltage GL₁ and the third bias voltage GT₁ are zero bias voltages or positive bias voltages, and both the fourth bias voltage and the fifth bias voltage are positive bias voltages and are maintained for a second time.

During the second time, the negative electric field between the source 2 and the drain 3 pushes the electrons stored in the first floating gate 42, the second floating gate 52 or the third floating gate 62 that is connected to the negative bias voltage to the source 2 or the electrons are attracted to the drain 3, so as to complete the erasure of data.

Preferably, both the first time of the program state and the second time of the erase state are less than one second.

When the unit cell 100 is operated in the stand-by state, the first bias voltage GR₁, the second bias voltage GL₁, the third bias voltage GT₁, the fourth bias voltage and the fifth bias voltage are between −3 and +0 volts, respectively.

When the unit cell 100 is operated in one of the read state, the program state and the erase state, the first bias voltage GR₁, the second bias voltage GL₁, the third bias voltage GT₁, the fourth bias voltage and the fifth bias voltage are between −10 and +20 volts, respectively.

When in the stand-by state, the third bias voltage GT₁ is a negative bias voltage, which can reduce the punch-through current between the source 2 and the drain 3, avoid unnecessary power waste, and prevent a data error caused by an unintended leakage current of the first floating gate 42 or the second floating gate 52.

In order to further ensure that the data is correct, a control unit, such as the chip 200 shown in FIG. 8, may be electrically connected to the unit cell 100.

After the unit cell 100 is operated in the program state or the erase state, the unit cell 100 is operated in the read state and the control unit executes a check process.

When the control unit detects an error through the check process, the unit cell 100 is operated in the program state or the erase state again, and then is operated in the read state. The control unit re-executes the check process. The control unit counts the number of checks.

The error means that after the program state ends, the unit cell 100 cannot read the program data, or after the erase state ends, the unit cell 100 still stores data that has not been erased.

At this time, the control unit re-controls the unit cell 100 to be in the program state or the erase state for performing the check process again and add one to the number of checks.

When the control unit detects that there is no error through the check process, the control unit erases the number of checks.

When the number of checks is greater than an allowable number, the control unit outputs an abnormal message, such as an error code or text message indicating that the data cannot be reprogrammed.

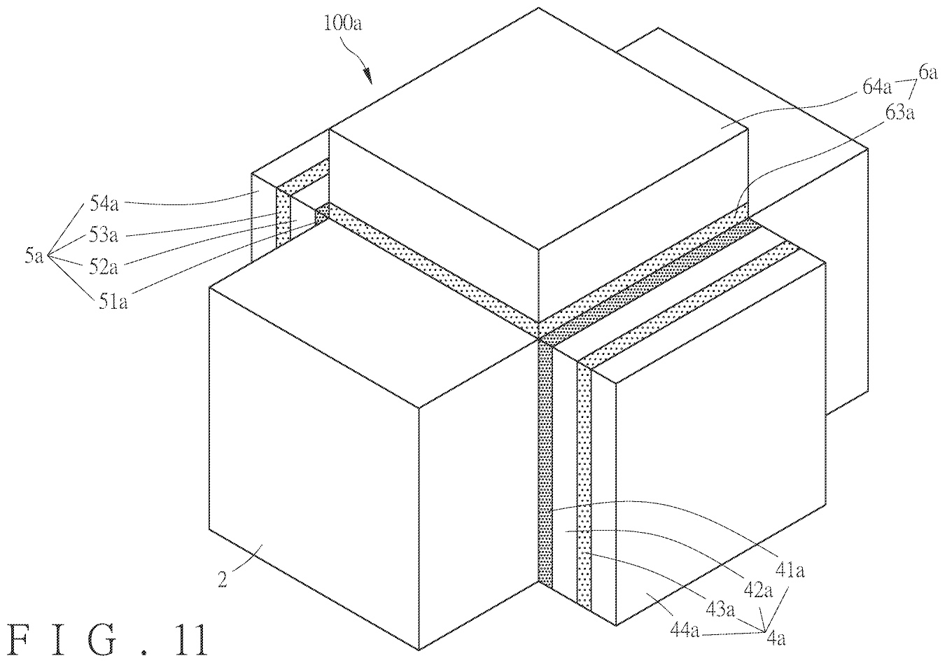

FIG. 11 illustrates a second embodiment of the non-volatile memory cell provided by the present invention. Two of the first part 4a, the second part 5a and the third part 6a of each unit cell 100a have the oxide layer, the floating gate, the insulating layer and the control gate. The remaining one of the first part 4a, the second part 5a and the third part 6a of each unit cell 100a has the insulating layer and the control gate.

As shown in FIG. 11, the first part 4a has the first oxide layer 41a, the first floating gate 42a, the first insulating layer 43a and the first control gate 44a; the second part 5a has the second oxide layer 51a, the second floating gate 52a, the second insulating layer 53a and the second control gate 54a; and the third part 6a has the third insulating layer 63a and the third control gate 64a, but not limited thereto.

When the non-volatile memory cell of this embodiment is operated in the stand-by state, the read state, the program state or the erase state, depending on whether the unit cell 100a is arranged in a NOR structure or a NAND structure, the operation steps correspond to those in the first embodiment, and will not be repeated herein.

In this way, each unit cell 100a can store two bits of data, which is beneficial to increase the memory capacity while reducing the size, and even simplify the manufacturing process and reduce production costs.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. A non-volatile memory cell, comprising:
at least one unit cell, including:
a fin channel, extending in a Y direction;
a source, adjacent to one end of the fin channel in the Y direction;
a drain, adjacent to another end of the fin channel in the Y direction;
an oxide layer, including a first oxide layer, a second oxide layer and a third oxide layer;
a floating gate, including a first floating gate, a second floating gate and a third floating gate;
an insulating layer, including a first insulating layer, a second insulating layer and a third insulating layer;
a control gate, including a first control gate, a second control gate and a third control gate;
a first part, adjacent to one side of the fin channel in an X direction, the X direction being perpendicular to the Y direction, the first part including, in sequence, the first oxide layer close to the fin channel, the first floating gate, the first insulating layer, and the first control gate far away from the fin channel;
a second part, adjacent to another side of the fin channel in the X direction, the second part including, in sequence, the second oxide layer close to the fin channel, the second floating gate, the second insulating layer, and the second control gate far away from the fin channel; and
a third part, adjacent to the fin channel in a Z direction, the Z direction being perpendicular to the X direction and the Y direction, the third part including the third oxide layer close to the fin channel, the third floating gate, the third insulating layer, and the third control gate far away from the fin channel.

2. A non-volatile memory cell, comprising:
at least one unit cell, including:
a fin channel, extending in a Y direction;
a source, adjacent to one end of the fin channel in the Y direction;
a drain, adjacent to another end of the fin channel in the Y direction;
a first part, adjacent to one side of the fin channel in an X direction, the X direction being perpendicular to the Y direction;
a second part, adjacent to another side of the fin channel in the X direction; and
a third part, adjacent to the fin channel in a Z direction, the Z direction being perpendicular to the X direction and the Y direction;
wherein two of the first part, the second part and the third part each include, in sequence, an oxide layer close to the fin channel, a floating gate, an insulating layer, and a control gate far away from the fin channel;
wherein the remaining one of the first part, the second part and the third part includes, in sequence, the insulating layer close to the fin channel and the control gate far away from the fin channel;
wherein the control gate of the first part is defined as a first control gate, the control gate of the second part is defined as a second control gate, and the control gate of the third part is defined as a third control gate.

3. The non-volatile memory cell as claimed in claim 2, wherein the oxide layer includes one of silicon dioxide, hafnium dioxide and zirconium dioxide, or a combination thereof; the insulating layer includes one of silicon dioxide, zirconium dioxide, hafnium dioxide and silicon nitride, or a combination thereof.

4. The non-volatile memory cell as claimed in claim 2, wherein the fin channel includes a first substrate adjacent to the drain, an anti-punch-through region adjacent to the first substrate, and a second substrate adjacent to the anti-punch-through region and the source.

5. The non-volatile memory cell as claimed in claim 2, wherein the first control gate is connected to a first bias voltage, the second control gate is connected to a second bias voltage, the third control gate is connected to a third bias voltage, the drain is connected to a fourth bias voltage, the source is connected to a fifth bias voltage, the unit cell is operated in one of a stand-by state, a read state, a program state and an erase state; when in the stand-by state, the first bias voltage, the second bias voltage and the third bias voltage are negative bias voltages, the fourth bias voltage is a zero bias voltage or positive bias voltage, and the fifth bias voltage is a zero bias voltage; when in the read state, one of the first bias voltage, the second bias voltage and the third bias voltage and the fourth bias voltage are positive bias voltages, the fifth bias voltage is a zero bias voltage, the remaining two of the first bias voltage, the second bias voltage and the third bias voltage are negative bias voltages; when in the program state, one of the first bias voltage, the second bias voltage and the third bias voltage and the fourth bias voltage are positive bias voltages, the fifth bias voltage is a zero bias voltage, and the remaining two of the first bias voltage, the second bias voltage and the third bias voltage are negative bias voltages and are maintained for a first time; when in the erase state, one of the first bias voltage, the second bias voltage and the third bias voltage is a negative bias voltage, the remaining two of the first bias voltage, the second bias voltage and the third bias voltage are zero bias voltages or positive bias voltages, and both the fourth bias voltage and the fifth bias voltage are positive bias voltages and are maintained for a second time.

6. The non-volatile memory cell as claimed in claim 5, wherein when the unit cell is operated in the stand-by state, the first bias voltage, the second bias voltage and the third bias voltage are between −3 and +0 volts, respectively; when the unit cell is operated in one of the read state, the program state and the erase state, the first bias voltage, the second bias voltage, the third bias voltage, the fourth bias voltage and the fifth bias voltage are between −10 and +20 volts, respectively.

7. The non-volatile memory cell as claimed in claim 5, wherein a control unit is electrically connected to the unit cell; after the unit cell is operated in the program state or the erase state, the unit cell is operated in the read state and the control unit executes a check process; when the control unit detects an error through the check process, the unit cell is operated in the program state or the erase state again, and then is operated in the read state, the control unit re-executes the check process, the control unit counts the number of checks; the control unit erases the number of checks until the control unit detects that there is no error through the check process; or the control unit outputs an abnormal message when the number of checks is greater than an allowable number.

8. The non-volatile memory cell as claimed in claim 5, wherein both the first time of the program state and the second time of the erase state are less than one second.

9. The non-volatile memory cell as claimed in claim 2, wherein the control gate is doped with an impurity, and the impurity includes one of phosphorus, arsenic, antimony, boron and aluminum, or a combination thereof.

10. The non-volatile memory cell as claimed in claim 2, wherein the source, the drain and the fin channel are each doped with an impurity having a same polarity; when the unit cell is an n-type channel cell, the impurity doped in the source and the drain includes one of phosphorus, arsenic and antimony, or a combination thereof; when the unit cell is a p-type channel cell, the impurity doped in the source and the drain includes boron and/or aluminum.

11. The non-volatile memory cell as claimed in claim 10, wherein the impurity doped on a surface of the fin channel has a surface concentration, a concentration of the impurity doped below the fin channel is lower than the surface concentration at a depth near the surface of the fin channel, below the depth, the concentration of the impurity increases to a multiple of the surface concentration and then gradually decreases in the Z-direction.

12. The non-volatile memory cell as claimed in claim 2, wherein the at least one unit cell includes a plurality of unit cells, the drains of the unit cells are connected to each other and the sources of the unit cells are connected to each other to form a NOR structure.

13. The non-volatile memory cell as claimed in claim 2, wherein the at least one unit cell includes a plurality of unit cells, the source of at least one of the unit cells is connected to the drain of an adjacent one of the unit cells to form a NAND logic gate structure.
